(19) United States
(12) Patent Application Publication
(10) Pub. No.: US 2016/0254822 A1
(43) Pub. Date: Sep. 1, 2016

(54) Capacitor with Switch and Circuit Containing Capacitor with Switch

(71) Applicant: Mitsutoshi Sugawara, Kanagawa (JP)

(72) Inventor: Mitsutoshi Sugawara, Yokohama-shi (JP)

(21) Appl. No.: 14/392,382

(22) PCT Filed: Oct. 14, 2013
(86) PCT No.: PCT/JP2013/077872

§ 371 Date: Mar. 9, 2016

(30) Foreign Application Priority Data
Sep. 22, 2013 (JP) 2013-196295

(51) Int. Cl. H03M 1/66; H01L 23/535; H03M 1/12; H01L 27/06

(52) U.S. Cl. CPC H03M 1/66; H01L 27/0629; H01L 23/535; H03M 1/12

(57) ABSTRACT

The present application pertains to a circuit such that a capacitor within an IC or LSI can be switched by means of switch. The circuit has a plurality of circuits resulting from one end of capacitor that uses the wiring in an LSI being connected to a switch configured from a MOS transistor, and is characterized by the direction of the long sides (fingers) of the electrode of the capacitor being the same direction as that of the long side of the gate of the MOS transistor, and the repetition pitch when arranging a plurality thereof being identical to each other or an integer multiple of another.

### BACKGROUND OF THE INVENTION

### Field of the Invention

This invention relates to a capacitor-with-switch circuit in an integrated circuit (IC) or large scale IC (LSI).

A circuit containing capacitor with switch is popular in analog filter, A to D converter (ADC), oscillator (OSC), etc. It was popular to fabricate MIM capacitors, which consist of insulator thin film between metal layers, and MOS switches, and to connect them with metal wires. Recently semiconductor processes become sub-micron (0.1 micro-meter), and wire-space becomes narrower than the insulator thickness. Therefor MOM capacitor, which consists of wire-space, is better area-efficient.

### REFERENCE DOCUMENTS

1) Japan Patent Application #2013-120857 “Semiconductor Integrated Circuit” inventor Urayama.

2) Japan Patent Application #2008-263185 “Semiconductor Integrated Circuit” inventor Ueno.

Even though these patent documents describe to place analog elements as an array, these elements are provided in certain size, such as 1 micro-meter˜100 micro-meters, placed them, and then routed them. There are none for MOM capacitors.

Since capacitor and MOS switch are provided in certain sizes, then connected them with metal wires previously, they respectively require 1˜10 micro-meter squares including their isolation areas. In addition, wiring stray capacitances effect lower accuracy or lower performance. Due to the stray capacitances, the smallest switchable capacitance resolution is practically 100 fF.

This invention realizes to decrease the stray cap/opnode T1, and another node is respectively connected to one of switches S1˜S4, consisting of MOS transistor. Another nodes of the switches are connected together to node T2. Small squares means contact holes. A narrow white rectangle means a gate electrode of the MOS transistor, and is connected to control logic signal respectively (not shown in the figure). FIG. 3b shows a cross section view at double dotted line in FIG. 3a.

Since these two examples consist of individual generations of capacitors and switch transistors and connections between them, they are not only bigger size, but also low accuracy or bad performance due to the stray capacitances of the connection wires. In the fact, minimum resolution of switchable capacitance is limited to approximate 100 fF or more, because of the stray capacitance.

### Advantages of this Invention

By applying this invention, we can realize 1 fF resolution for capacitor switching by reducing stray wire capacitance. In addition, it is possible to guarantee monotonicity.

### SUMMARY OF THE INVENTION

### Meanings to Solve the Problem

This invention earns a lot of merits, by fitting repeating-pitch between capacitor and switch as follows.

This invention is an LSI, including wires to connect between MOM capacitor, which consists of metal wire spaces, and switch, which consists of MOS transistor, wherein;

the same directions between electrode finger of said capacitor and gate of said MOS transistor,

adjacent placement of plural said capacitors and switches,

equal repeating-pitch or an integer multiple number of repeating-pitch of either said capacitors or said transistors,

and short connections between said capacitors and said transistors.

Here it is important notice that said repeating-pitch can be only sub-micro-meter, so that layout size of said capacitors and switches becomes 1˜2 order smaller than previous layouts.

Or, the present application pertains to a circuit such that a capacitor within an IC or LSI can be switched by means of switch. The circuit has a plurality of circuits resulting from one end of capacitor that uses the wiring in an LSI being connected to a switch configured from a MOS transistor, and is characterized by the direction of the long sides (fingers) of the electrode of the capacitor being the same direction as that of the long side of the gate of the MOS transistor, and the repetition pitch when arranging a plurality thereof being identical to each other or an integer multiple of another.

### DESCRIPTION OF THE REFERENCED ENBODIMENTS

FIG. 4 shows the first embodiment of this invention, and it has been adjusted equal repeating-pitch between 2 fingers of a MOM capacitor and 2 gates of a MOS transistor switch. Since typical LSI design rule requires narrower minimum gate pitch of the transistor than minimum finger pitch of the MOM capacitor, we need to design slightly wider gate pitch of the transistor to be equal to finger pitch of the MOM capacitor, but not limited.

For example, 2 fingers of the MOM capacitor C11 are connected to drains of the MOS transistor switch, said transistor's 2 gates are connected to common control signal (not shown in FIG. 4), and 2 sources are connected to node T2. Right side source of S11 is commonly shared with left side source of S12. This structure is repeated similarly to C25 and S25. Since the shared source structure can realize sub-micro-meter-order pitch, and doesn't require isolation region, it can realize significantly smaller total transistor area.

By controlling 2 gates of switch S11, capacitance 0.1 pF can be turned on/off. By controlling total 4 gates of switches S12 and S13, capacitance 0.2 pF can be turned on/off. By controlling total 8 gates of switches S14, S15, S16, and S17, capacitance 0.4 pF can be turned on/off. By controlling total 16 gates of switches S18˜S25, capacitance 0.8 pF can be turned on/off. Combining above controls, 0˜1.5 pF with 0.1 pF step can be set.

As another control style, by controlling 2 gates of switch S18, capacitance 0.1 pF can be turned on/off. By controlling total 4 gates of switches S14 and S22, capacitance 0.2 pF can be turned on/off. By controlling total 8 gates of switches S12, S16, S20, and S24, capacitance 0.4 pF can be turned on/off. By controlling total 16 gates of switches S11, S13, S15, S17, S19, S21, S23, and S25, capacitance 0.8 pF can be turned on/off. Combining above controls, 0˜1.5 pF with 0.1 pF step can be set. In the case, relative accuracy becomes better, due to averaging each capacitance, even if finger spaces may have gradient on a chip.

As the other control style, by turning all switches off, the capacitance is 0 pF. By turning switch S11 on, the capacitance is 0.1 pF. By turning switches S11 and S12 on, the total capacitance is 0.2 pF. By turning switches S11, S12, and S13 on, the total capacitance is 0.3 pF. By turning switches S11, S12, S13, and S14 on, the total capacitance is 0.4 pF . . . . By turning switches S11˜S25 on, the capacitance is 1.5 pF. This type of progressive control is called “thermometer code control”. In the type, total capacitance increases progressively, so that monotonicity is guaranteed. It is quite better especially in feedback loop. This type control is designed only digital side, without any modification in analog side which is shown in FIG. 4.

As more other control style, by turning all switches off, the capacitance is 0 pF. By turning switch S18 on, the capacitance is 0.1 pF. By turning switches S18 and S14 on, the total capacitance is 0.2 pF. By turning switches S18, S14, and S22 on, the total capacitance is 0.3 pF. By turning switches S11, S12, S13, and S14 on, the total capacitance is 0.4 pF . . . . By turning switches S11˜S25 on, the capacitance is 1.5 pF. This type of progressive control is also called “thermometer code control”. As well as guaranteed monotonicity, control of not-concentrated switch positions increases relative accuracy due to averaging each capacitance, even if finger spaces may have gradient on a chip. This type control is also designed only digital side, without any modification in analog side which is shown in FIG. 4.

These 3 control styles above are realized by placing switch per unit MOM capacitor (2 fingers in above cases) as an embodiment of this invention.

FIG. 5 shows the second embodiment of this invention. Capacitors C11˜C25 consist of 2 fingers respectively as same as FIG. 4. However, switches S11˜S25 and S11′˜S25′ are located in 2 rows, and connected to a finger of each capacitor respectively. This structure gains half capacitance resolution than FIG. 4. Or it earns one more bit. Any controls at digital side, described in the first embodiment, can be applicable.

FIG. 6 shows the third embodiment of this invention, and capacitors C11˜C25 have 2 gate-pitch of MOS transistors of switches S11˜S25. In typical LSI design rule, twice of a MOS transistors' minimum gate pitches is wider than a MOM capacitor's finger pitch, so that it is required to widen either finger width or finger space of the capacitor or both to be equal to MOS transistors' pitches. But not limited. Unit capacitance and/or finger number are not requested as exactly same as FIG. 4a or FIG. 5.

In this case, MOS transistor can work at best condition due to minimum pitch or minimum size.

Any controls at digital side, shown in the first embodiment, can be applicable.

FIG. 7 shows an example of DA converter (DAC) schematic by applying both conventional and this invention. Connecting node T1 as output, node T2 as ground (GND), and T3 as a voltage source or reference voltage, the DAC outputs analog voltage on to node T1 corresponding to S31˜S47 and S31′˜S47′.

Typical conventional DAC has binary-weighted capacitances for capacitors C31˜C37 and C41˜C47 respectively.

C41˜C47 correspond to multiple MSB bits, and C31˜C37 correspond to multiple LSB bits.

As well known, capacitors C40 and C40′ are scaling capacitors to be approximate equal to C41 for sum of C31˜C37, and typical value is 1˜2 times of C41.

Appling this invention, C31˜C37 and C41˜C47 should be unit MOM capacitors.

FIG. 8 shows the fourth embodiment of this invention. C31˜C37 and C41˜C47 are single finger MOM capacitors, and switches S31˜S47 and S31′˜S47′ consist of MOS transistors. It is possible to place in equal pitches for a MOM capacitor and switches in plural rows in same pitch. In the example, the DAC outputs certain voltage by selected MOM capacitors C41˜C47 by switches controlled with given upper 4 bit data. Either binary code or thermometer code, described in first embodiments, is applicable for this control. Similarly above, the DAC outputs certain voltage by selected MOM capacitors C31˜C37 by switches controlled with given lower 4 bit data. Either binary code or thermometer code, described in first embodiments, is applicable for this control (gate connections are not shown). In the example, C40 and C40′ consist of same unit capacitors. It is popular to adjust scaling value by connecting additional capacitors to lower-side in parallel at left side of C31 (not shown in FIG. 8).

There is a shield electrode between C37 and C40′, and connected to node T1 as GND. Generally S31˜S47 consist of N channel MOS transistors and S31′˜S47′ consist of P channel MOS transistors (back gate connections are not shown in FIG. 8). Connections between each common source to node T2 or T3 can consist of upper metal layers over the transistors through via-on-via structure.

By placing MOM capacitors and switches in equal pitches, the schematic shown in FIG. 7 can be laid out with quite regularity to FIG. 8. It is higher density placement than conventional layout, because conventional isolation and shield areas for discrete transistor and capacitor generation are not required. And it has no interferences between themselves. In addition, neighbor environment of whole capacitors and switches can be same, when placing transistors in same pitch between S37˜S41 and S37′˜S41′, placing only a shield line in same pitch, and placing dummy capacitors and dummy switches (not shown in FIG. 8) at both very ends in same pitch. The layout expects to increase relative accuracy.

Unit capacitors and switches described in the first˜third embodiments can be also applied into this embodiment. Unit capacitance value and/or finger number are selectable, corresponding to required bit number, etc. Positions of scaling capacitors C40 and C40′ are not limited in FIG. 8. They can be placed, for example, at right-side of C37, left-side of C31, etc. anywhere without changing their pitches. Number of switch rows can increase, for example, for input injection switches for AD converter (ADC). Polarities of the switching transistors are not limited in FIG. 8, and is selectable, including N and P in parallel.

FIG. 9 shows the fifth embodiment of this invention, and it is an example of C40′ as a half value of unit MOM capacitance. Here total scaling capacitance of C40 and C40′ is approximate 1.5 times of the unit capacitance. This example is smaller than the fourth embodiment.

FIG. 10a shows typical gate-level schematic of D-flip-flop (DFF) for conventional and this invention, and FIG. 10b shows its typical transistor-level schematic.

FIG. 10c shows the sixth embodiment of this invention, and it is a layout of FIG. 10a and FIG. 10b. It has 4 gate-transistor width, and sources at both ends, which are connected to power sources such as VDD or GND. Therefore when place the DFFs, the sources can be shared with neighbors' sources, and they are continuously laid out in 4 gate-pitch.

In FIG. 10c, there are N channel MOS transistors in the top row, P channel MOS transistors in the second row, P channel MOS transistors in the third row, and N channel MOS transistors in the bottom row (back gates connections are not shown in FIG. 10c). It is wired with gate-layer for gate and its lead on thick SiO₂, wires colored by dark gray, and wires on another layer colored by black. Gate widths at vertical direction are not require equal in FIG. 10c.

This embodiment demonstrates layout of a DFF in 4 gate-pitch as an example, so that internal transistor positions and connections are not limited in FIG. 10c.

FIG. 11 shows the seventh embodiment of this invention, and it is combined with MOM capacitors with switches shown in FIG. 9 and DFFs shown in FIG. 10c. It clearly shows DFF, as an example of control logic, in same pitch in addition to capacitors with switches.

In this embodiment, 2 fingers of unit capacitor, 4 gate MOS transistor for switch, and a DFF are placed in line with same pitch. A group of S42, S42′, S43, S43′, a group of S44, S44′, S45, S45′, and a group of S46, S46′, S46, S46′ are controlled by a single DFF respectively. For example, the DAC outputs analog voltage at node T1, corresponding to upper 4 bit input, through S41 and S41′ controlled by binary code, and other switches controlled by thermometer code. The DAC outputs analog voltage at node T1, corresponding to lower 4 bit similarly.

For more regularity, C40′ is slightly modified to get accurate half capacitance.

In addition, wiring channel area between logic and switches is not needed, and then total area should be smaller than conventional layout. Placing dummy capacitor, dummy switches and dummy logic gates at both very ends, neighbor environment of whole unit capacitors, switches, and logic can be exactly same, therefore relative accuracy increases. Since whole load capacitances of the logic, including wire stray capacitances and switches' input capacitances are same, switching time of whole switches are also same.

The relation between MOM capacitor and switches in FIG. 11 can apply one of the first˜sixth embodiments above. Bit number, number of switches, and polarities can be selectable.

A key relationship of this invention is that equal pitch or multiple number of pitch of others between MOM capacitors and switches. In addition, similar relation among them and logic for this embodiment. For example, placing DFFs in 2 rows and wiring through plural layers, [S42, S42′], [S43, S43′], . . . [S47, S47′] can respectively be controlled individually in same pitch (not shown in FIG. 11).

In addition to DFF, logic related to selecting switches can also be placed in same pitch (not shown in FIG. 11). Without DFF, only logic related to selecting switches can also be placed in same pitch or multiple pitch (not shown in FIG. 11). As an example, the “logic related to selecting switches” may be thermometer coder, and/or gate-delay equalizing circuit.

FIG. 12 shows the eighth embodiment of this invention, it is combined with 2 set of capacitors with switches shown in FIG. 9 and inductor L1. The capacitors with switches and inductor L1 make a resonation circuit, and it can be widely selectable resonant frequency by selecting the switch digitally. A high frequency analog circuit, connecting to nodes T1 and T2 (not shown in FIG. 12) can be digitally variable frequency filter. Or an oscillator, connecting to nodes T1 and T2 (not shown in FIG. 12) can be digitally control oscillator (DCO).

FIG. 13 shows layout example of FIG. 12.

Typical Frequency control of conventional LC-resonation circuit includes varactor diode, whose capacitance is controlled by analog bias voltage. This embodiment has more affinity with digital circuit, due to frequency control by digitally switching on/off.

### INDUSTRIAL APPLICABILITY

conventional capacitors and switches are placed and connected as individual parts, however this invention has recognized them as “capacitor(s) with switch(es)”. And this invention is created to place plural of them regularly in same pitch or multiple pitch of others. Especially since MOM capacitor becomes better area-efficient in finer CMOS process, “capacitor(s) with switch(es)” can be easily realized. This invention is not limited to the embodiments above, and unit capacitance, finger number of unit capacitor, control bit number, and control logic can be accordingly modified.

### BRIEF DESCRIPTION OF THE DRAWINGS

FIG. 1 is an example schematic for conventional and this invention.

FIG. 2a is an example of conventional layout of FIG. 1, and FIG. 2b is its cross section.

FIG. 3a is another example of conventional layout of FIG. 1, and FIG. 3b is its cross section.

FIG. 4 is the first embodiment, and a layout of FIG. 1.

FIG. 5 is the second embodiment.

FIG. 6 is the third embodiment.

FIG. 7 is an example schematic for conventional and this invention.

FIG. 8 is the fourth embodiment.

FIG. 9 is the fifth embodiment.

FIG. 10a is an example of D-flip-flop gate-level schematic for conventional and this invention. FIG. 10b is an example of D-flip-flop transistor-level schematic for conventional and this invention. FIG. 10c is the sixth embodiment.

FIG. 11 is the seventh embodiment.

FIG. 12 is the eighth embodiment of schematic.

FIG. 13 is the eighth embodiment of layout.

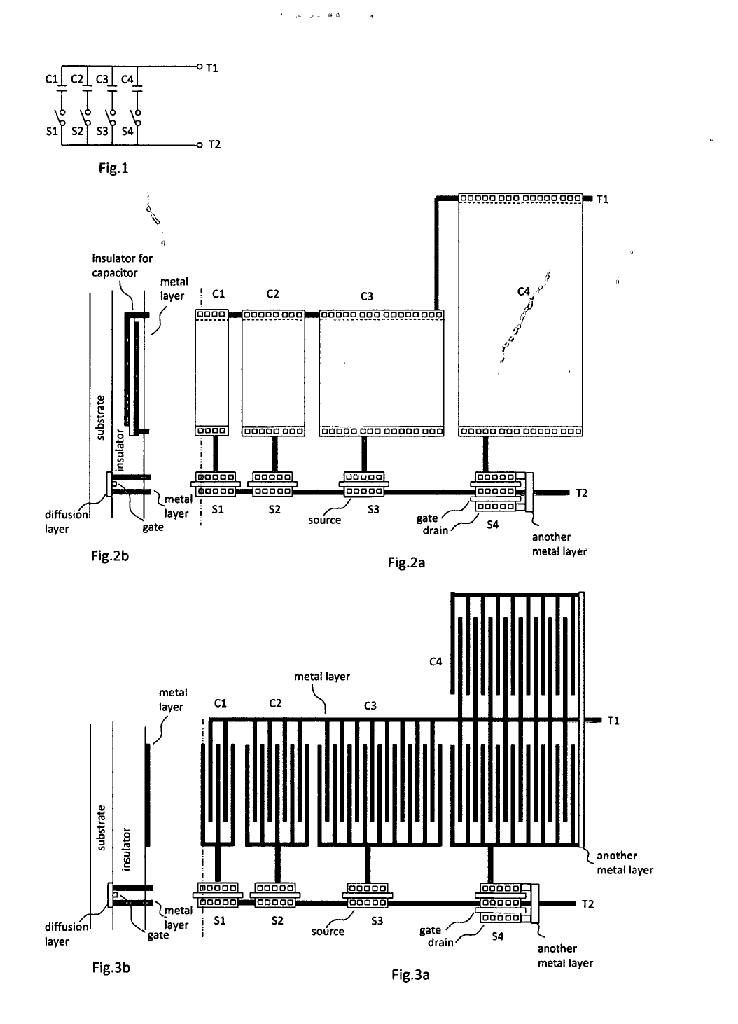

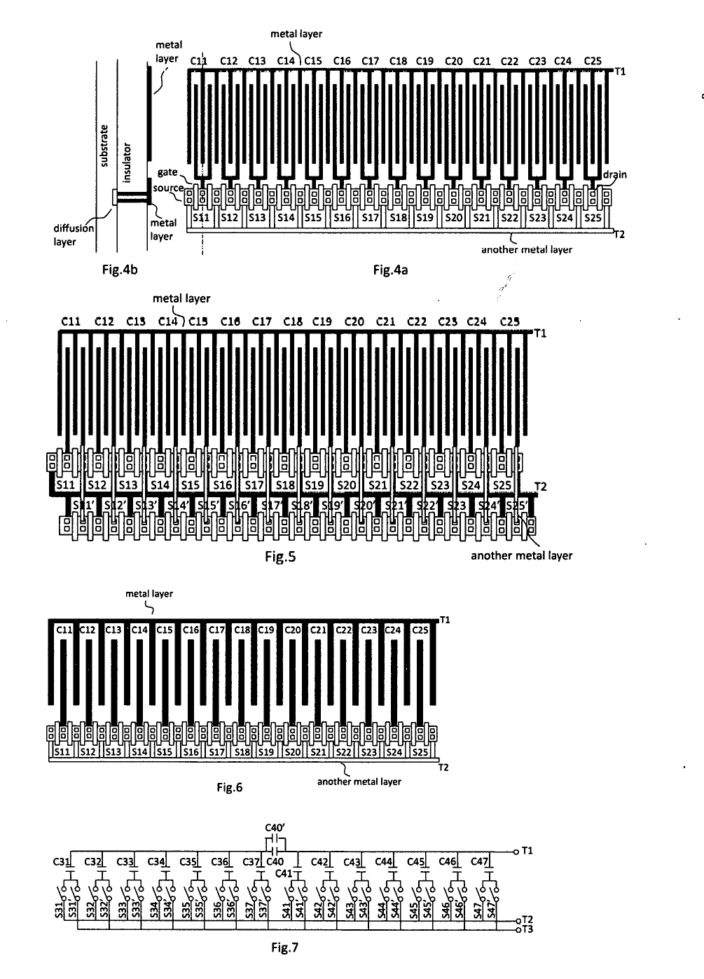

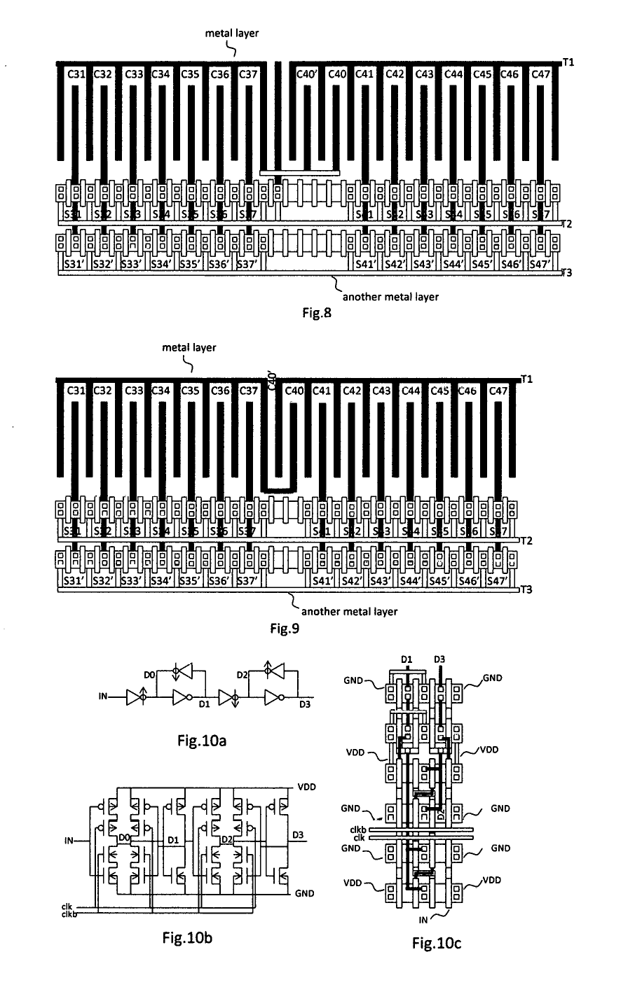

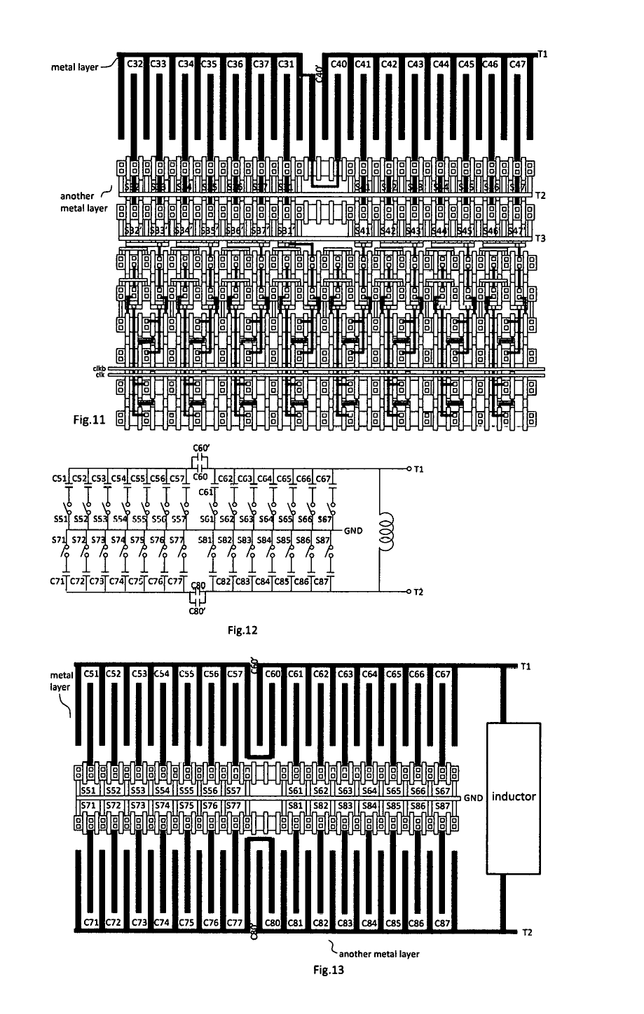

Explanations of Symbols are below;
C1˜C87 capacitor in an LSI
S1˜S87, S1′˜S87′ switch consisting of MOS transistor
L1 inductor

What is claimed is:

1. (canceled)

2. A capacitor-with-switch circuit consisting of:
plural number of capacitors by using spaces between wiring materials on an LSI;
MOS transistor switches connected to said each capacitor's first electrode respectively;
wherein:
fingers of said capacitor's electrodes and gates of said MOS transistors placed same direction, with same or integer multiple pitch of the others as tiles;
drains of said MOS transistors connected to said first electrodes of said capacitors respectively;
sources of said MOS transistors, having common-source structure shared with neighbor transistor(s), and connected together to a first node;
gates of said MOS transistors, receiving switch control signal respectively;
and each second electrode of said capacitor, connected together to a second node.

3. A capacitor-with-switch circuit described in claim 2,
wherein
said each gate consists of two fingers respectively.

4. A capacitor-with-switch circuit described in claim 2,
wherein:
said each receiving switch control signal at each gate is binary-coded signal,
said MOS transistor switches, commonly controlled by each number, which is in proportion to each weight of said each binary bit.

5. A capacitor-with-switch circuit described in claim 4,
wherein
said MOS transistor switches, whose locations are not-concentrated or scrambled.

6. A capacitor-with-switch circuit described in claim 2,
wherein
said each receiving switch control signal at each gate is thermometer-coded signal, which progressively increases turn-on-number of MOS transistor switches.

7. A capacitor-with-switch circuit described in claim 6,
wherein
said MOS transistor switches, controlled by thermometer-code, whose locations are not consecutive per code.

8. A capacitor-with-switch circuit described in claim 6,
wherein
said MOS transistor switches, located in multiple rows.

9. Plural capacitor-with-switch circuits described in claim 2, connected them through a third capacitor(s),
wherein
said third capacitor(s), continuously located with said plural capacitor-with-switch circuits in same pitch as said capacitor-with-switch.

10. A capacitor-with-switch circuit described in claim 2, with its control circuit,
wherein
MOS transistors in said control circuit, in same pitch as said MOS transistor switch.

11. A capacitor-with-switch circuit described in claim 10,
wherein
said control circuit, including D-flip-flops.

12. A capacitor-with-switch circuit described in claim 10,
wherein
said control circuit, including thermometer coder circuit.

13. A capacitor-with-switch circuit described in claim 10,
wherein
said control circuit, including gate-delay-adjuster circuit.

14. A capacitor-with-switch circuit described in claim 10,
wherein
said control circuit, located in multiple rows.

15. A capacitor-with-switch circuit described in claim 10,
wherein
transistors in said control circuit, consisting of 4 gate transistors as a unit whose both end electrodes are source electrodes shared with neighbors.

16. A digitally controlled resonator including capacitor-with-switch circuit described in claim 2, combining with an inductor.

17. A DA converter which includes said capacitor-with-switch circuit described in claim 2.

18. An AD converter which includes said capacitor-with-switch circuit described in claim 2.
